(19) United States
(12) Patent Application Publication
(10) Pub. No.: US 2014/0254096 A1
(43) Pub. Date: Sep. 11, 2014

(54) ELECTRONIC APPARATUS

(71) Applicant: Kabushiki Kaisha Toshiba, Tokyo (JP)

(72) Inventor: Nobuto FUJIWARA, Hamura-shi (JP)

(73) Assignee: Kabushiki Kaisha Toshiba, Tokyo (JP)

(21) Appl. No.: 13/968,156

(22) Filed: Aug. 15, 2013

Related U.S. Application Data
(63) Continuation of application No. PCT/JP2013/056503, filed on Mar. 8, 2013.

(51) Int. Cl. H05K 7/20

(52) U.S. Cl. CPC H05K 7/20136
USPC 361/695

(57) ABSTRACT

According to one embodiment, an electronic apparatus includes a housing, a fan, and an AC adapter. The fan is accommodated in the housing and has a fan casing at least a portion of which is made of metal. The AC adapter is removably accommodated in the housing and also thermally connected to the fan casing by being brought in contact with the portion of the fan casing in the housing.

### CROSS-REFERENCE TO RELATED APPLICATIONS

This application is a Continuation application of PCT Application No. PCT/JP2013/056503, filed Mar. 8, 2013, the entire contents of which are incorporated herein by reference.

### FIELD

Embodiments described herein relate generally to an electronic apparatus.

### BACKGROUND

An attempt is made to use, as a kind of next-generation power semiconductor, gallium nitride (GaN) as a power semiconductor device used, for example, for an AC adapter of a portable computer. An AC adapter using GaN can be expected to be made more compact and so can be incorporated into a housing of a portable computer.

An AC adapter using GaN can reduce the calorific value for reduced power losses. However, even if the calorific value of the AC adapter is reduced, the fact that the AC adapter is accompanied by heat generation remains unchanged. Thus, if the AC adapter is accommodated in the housing, there is no denying that the AC adapter is one of factors causing a temperature rise in the housing.

Therefore, measures to efficiently release heat generated by the AC adapter to the outside of the housing are urgently needed.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer showing a state in which an AC adapter is removed from an adapter receptacle of a first housing in a first embodiment.

FIG. 2 is an exemplary perspective view of the portable computer showing a state in which the AC adapter is accommodated in the adapter receptacle of the first housing in the first embodiment.

FIG. 3 is an exemplary sectional view of the portable computer showing the state in which the AC adapter is accommodated in the adapter receptacle of the first housing in the first embodiment.

FIG. 4 is an exemplary sectional view of the portable computer showing the state in which the AC adapter is removed from the adapter receptacle of the first housing in the first embodiment.

FIG. 5 is an exemplary sectional view showing a physical relationship between the AC adapter accommodated in the adapter receptacle and a centrifugal fan in the first embodiment.

FIG. 6 is an exemplary sectional view of a portable computer showing the state in which an AC adapter is removed from an adapter receptacle of a first housing in a second embodiment.

FIG. 7 is an exemplary sectional view of the portable computer showing the state in which the AC adapter is accommodated in the adapter receptacle of the first housing in the second embodiment.

FIG. 8 is an exemplary sectional view of a portable computer showing a state in which an AC adapter is accommodated in an adapter receptacle of a first housing in a third embodiment.

FIG. 9 is an exemplary sectional view of the portable computer showing the state in which the AC adapter is removed from the adapter receptacle of the first housing in the third embodiment.

FIG. 10 is an exemplary sectional view showing the physical relationship between a first air course along which a cooling air flows and the AC adapter in the third embodiment.

FIG. 11 is an exemplary sectional view showing a physical relationship between a first air course and a second air course along which a cooling air flows and an AC adapter in a fourth embodiment.

FIG. 12 is an exemplary sectional view of a portable computer showing a state in which an AC adapter is removed from an adapter receptacle of a first housing in a fifth embodiment.

FIG. 13 is an exemplary sectional view showing the physical relationship between a heat pipe embedded in a heat receiving unit and the AC adapter in the fifth embodiment.

FIG. 14 is an exemplary sectional view showing a physical relationship between a heat pipe placed above a heat receiving unit and an AC adapter in a sixth embodiment.

FIG. 15 is an exemplary perspective view of a portable computer showing a state in which an AC adapter is removed from an adapter receptacle of a first housing in a seventh embodiment.

FIG. 16 is an exemplary sectional view of the portable computer showing the state in which the AC adapter is removed from the adapter receptacle of the first housing in the seventh embodiment.

FIG. 17 is an exemplary sectional view of the portable computer showing the state in which the AC adapter is accommodated in the adapter receptacle of the first housing in the seventh embodiment.

FIG. 18 is an exemplary sectional view showing the state in which the AC adapter removed from the adapter receptacle of the first housing is connected to the portable computer via an output cable in the seventh embodiment.

FIG. 19 is an exemplary perspective view of a portable computer showing a state in which an AC adapter is removed from an adapter receptacle of a first housing in an eighth embodiment.

FIG. 20 is an exemplary sectional view of a portable computer showing a state in which an AC adapter is accommodated in an adapter receptacle of a first housing in a ninth embodiment.

FIG. 21 is an exemplary sectional view showing the physical relationship between the AC adapter accommodated in the adapter receptacle and a centrifugal fan in the ninth embodiment.

### DETAILED DESCRIPTION

Various embodiments will be described hereinafter with reference to the accompanying drawings. In general, according to one embodiment, an electronic apparatus includes a housing, a fan, and an AC adapter as an example of the heating module. The fan is accommodated in the housing and has a fan casing at least a portion of which is made of metal. The AC adapter is removably accommodated in the housing and also thermally connected to the fan casing by being brought in contact with the portion of the fan casing in the housing.

### First Embodiment

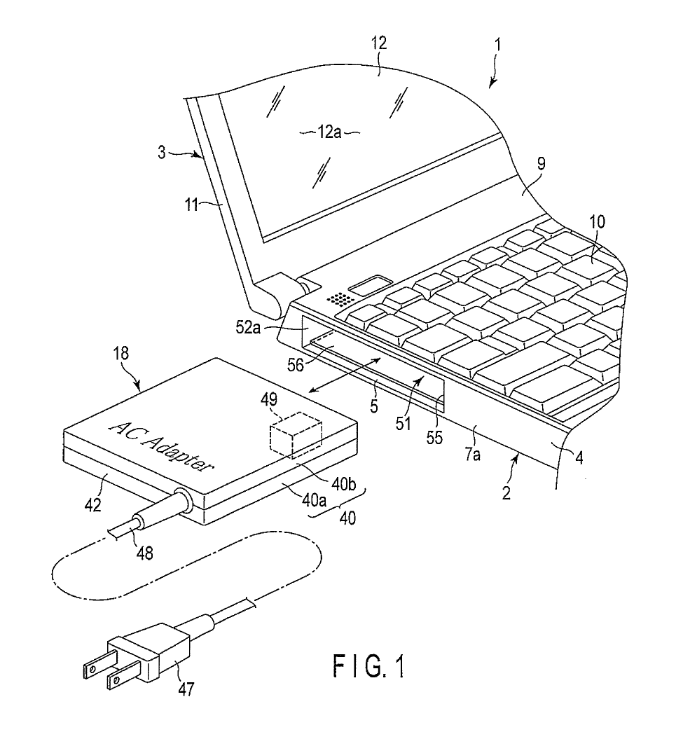

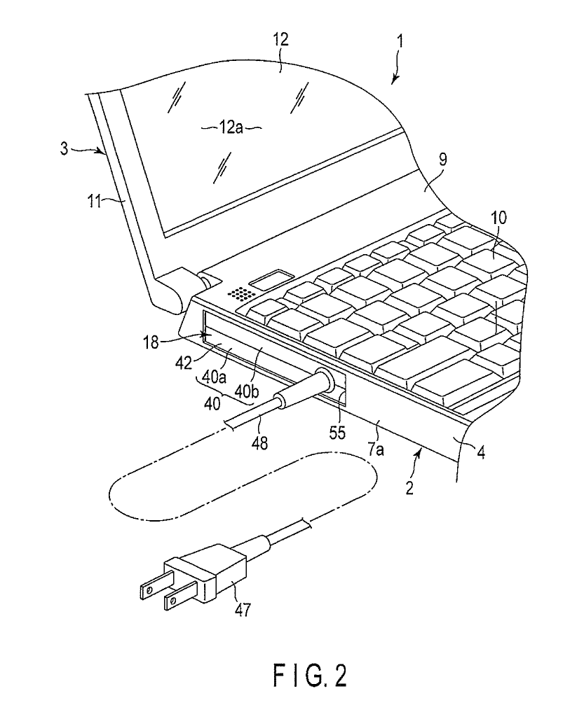

The first embodiment will be described below with reference to FIGS. 1 to 5.

FIGS. 1 to 3 disclose a portable computer 1 as an example of an electronic apparatus. The portable computer 1 includes a computer main body 2 and a display 3. The computer main body 2 has a first housing 4. The first housing 4 has a rectangular box shape including a bottom wall 5, a front wall 6, left and right sidewalls 7a, 7b, a rear wall 8, and a top wall 9. The front wall 6, the sidewalls 7a, 7b, and the rear wall 8 are examples of a circumferential wall and connect a circumference of the bottom wall 5 and a circumference of the top wall 9. A keyboard 10 is provided in the top wall 9 of the first housing 4.

The display 3 includes a second housing 11 and a liquid crystal display apparatus 12 accommodated in the second housing 11. The second housing 11 is rotatably supported via hinge fittings in a rear end portion of the first housing 4. The liquid crystal display apparatus 12 has a screen 12a that displays information like images. The screen 12a is exposed in the front of the second housing 11.

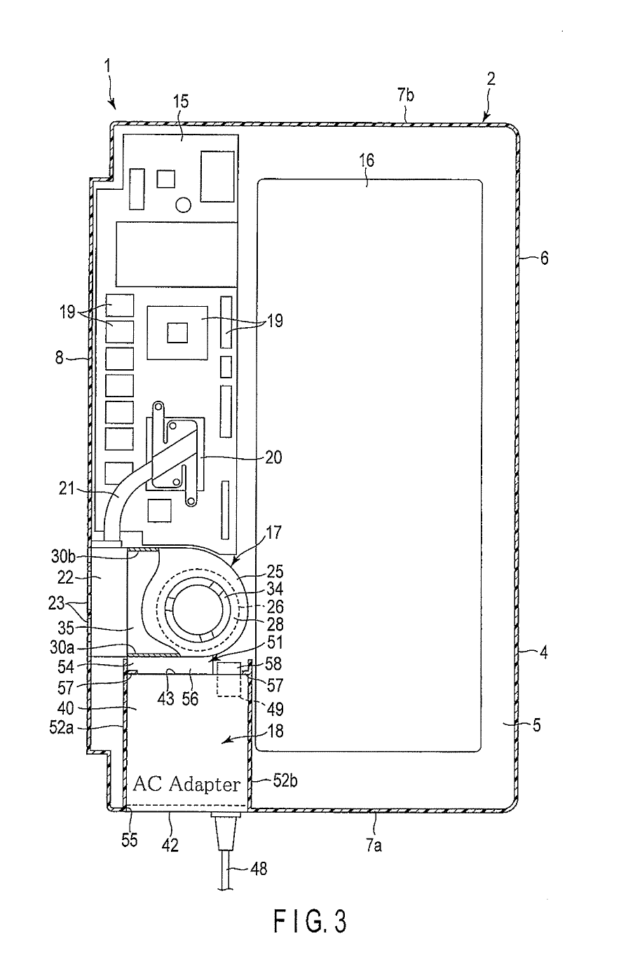

As shown in FIG. 3, a motherboard 15, a battery pack 16, a centrifugal fan 17, and an AC adapter 18 are accommodated inside the first housing 4.

The motherboard 15 is supported on the bottom wall 5 of the first housing 4 so as to be positioned in the rear half of the first housing 4. A plurality of circuit components 19 like a semiconductor package and connectors and a CPU 20 are mounted on the motherboard 15. The CPU 20 is an example of a heating component and is thermally connected to a heat sink 22 via a heat pipe 21. The heat pipe 21 transfers heat of the CPU 20 to the heat sink 22. The heat sink 22 is arranged in the rear end portion of the first housing 4 and faces a plurality of exhaust ports 23 opened in the rear wall 8.

The battery pack 16 is supported on the bottom wall 5 of the first housing 4 so as to be positioned in the front half of the first housing 4. The battery pack 16 is electrically connected to the motherboard 15.

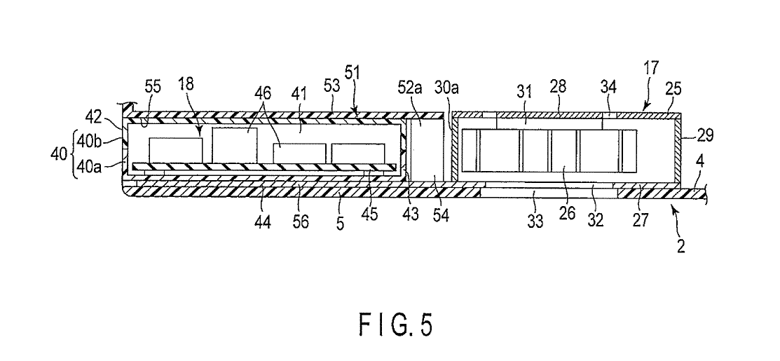

The centrifugal fan 17 is an element blowing a cooling air on the heat sink 22 and is fixed onto the bottom wall 5 by a publicly known method like screwing. As shown in FIG. 5, the centrifugal fan 17 includes a fan casing 25 and an impeller 26. The fan casing 25 has a flat box shape and is formed from a metal material, for example, a steel plate or aluminum alloy. The fan casing 25 has a first end plate 27, a second end plate 28, and a side plate 29.

The first end plate 27 and the second end plate 28 are arranged in parallel in the thickness direction of the fan casing 25 with a space therebetween. The first end plate 27 is an element constituting the bottom of the fan casing 25. The second end plate 28 is an element constituting the ceiling of the fan casing 25. The side plate 29 connects a circumference of the first end plate 27 and a circumference of the second end plate 28. The side plate 29 has a pair of linear portions 30a, 30b. The linear portions 30a, 30b are arranged in parallel with a space therebetween.

The impeller 26 is interposed between the first end plate 27 and the second end plate 28 and also surrounded by the side plate 29. Further, the impeller 26 is supported by the second end plate 28 via a fan motor 31.

As shown in FIG. 5, a first inlet port 32 is formed in the first end plate 27 as the bottom of the fan casing 25. The first inlet port 32 is opposed to the lower end of the impeller 26 and also connected to an air supply opening 33 opened in the bottom wall 5 of the first housing 4.

A second inlet port 34 is formed in the second end plate 28 as the ceiling of the fan casing 25. The second inlet port 34 is opposed to the upper end of the impeller 26 and also opened to the inside of the first housing 4.

An exhaust port 35 is formed between the linear portions 30a, 30b of the side plate 29 of the fan casing 25. The exhaust port 35 has a horizontal opening shape and is opposed to an outer circumferential portion of the impeller 26. Further, the exhaust port 35 is opposed to the heat sink 22 inside the first housing 4.

When the impeller 26 of the centrifugal fan 17 rotates, the air outside the first housing 4 is drawn into a rotation center portion of the impeller 26 through the air supply opening 33 and the first inlet port 32. Further, the air inside the first housing 4 is drawn into the rotation center portion of the impeller 26 through the second inlet port 34. The drawn air is discharged into the fan casing 25 from the outer circumferential portion of the impeller 26 as a cooling air.

As a result, a cooling air of predetermined pressure is discharged from the exhaust port 35 toward the heat sink 22. The discharged cooling air passes through the heat sink 22 before being exhausted out of the portable computer 1 from the exhaust ports 23 of the first housing 4.

Therefore, heat of the CPU 20 transferred to the heat sink 22 is released out of the first housing 4 by heat exchange with the cooling air.

The AC adapter 18 is an example of the heating module and transforms commercial AC power into suitable DC power adjusted to the portable computer 1 and outputs the transformed power. As shown in FIG. 5, the AC adapter 18 includes a case 40 made of synthetic resin and a switching regulator circuit module 41 accommodated in the case 40.

The case 40 is configured by combining a lower case 40a and an upper case 40b. The case 40 in the present embodiment is formed in a flat rectangular box shape having a front face 42, a rear face 43, and an undersurface 44.

The circuit module 41 includes a printed wiring board 45 and various circuit components 46 mounted on the printed wiring board 45. A power cord 48 having a power plug 47 is connected to an input terminal of the circuit module 41. The power cord 48 is led out of the AC adapter 18 from the front face 42 of the case 40. Further, an output plug 49 is arranged at an output terminal of the circuit module 41. The output plug 49 exposed to the outside of the AC adapter 18 from the rear face 43 of the case 40.

According to the present embodiment, the circuit components 43 of the circuit module 41 include a power semiconductor device used for power control. For the AC adapter 18 for a portable computer, a power semiconductor device of, for example, a few tens of V of withstand voltage and a few hundred KHz of switching frequency is demanded. Thus, in the present embodiment, a power semiconductor device made of gallium nitride (GaN) as a next-generation power semiconductor device is used.

GaN has characteristics, for example, the breakdown voltage and band gap are large when compared with silicon, the thermal conductivity is high, and the electron saturation speed is fast. Thus, when compared with a power semiconductor device made of silicon, a power semiconductor device made of GaN can perform a faster switching operation and has greater heat resistance.

More specifically, a power semiconductor device made of GaN can perform switching at a speed several times faster than a power semiconductor device made of silicon. With an increasing switching frequency, an element constituting a power converter such as an inductor can be made smaller.

In addition, a power semiconductor device made of GaN can operate even in a high-temperature environment of 200° C. or more, which is considered to be the upper limit of operation of a power semiconductor device made of silicon. Accordingly, a mechanism to cool a power converter can be made smaller or omitted.

As a result, the AC adapter 18 using a power semiconductor device made of GaN can be made smaller to a size allowing the AC adapter 18 to be accommodated inside the first housing 4.

The Such being the case, in the portable computer 1 in the present embodiment, as shown in FIGS. 1 to 5, an adapter receptacle 51 that accommodates the AC adapter 18 is provided inside the first housing 4. The adapter receptacle 51 is positioned at a left end in the rear end portion of the first housing 4 and is adjacent to the centrifugal fan 17.

The adapter receptacle 51 includes a pair of guide walls 52a, 52b and a top wall 53. The guide walls 52a, 52b are raised from the bottom wall 5 of the first housing 4. The guide walls 52a, 52b extend linearly in a width direction of the first housing 4 from a left sidewall 7a of the first housing 4 and are arranged in parallel in the depth direction of the first housing 4 with a space therebetween. Tips of the guide walls 52a, 52b positioned on the opposite side of the sidewall 7a reach immediately before the one linear portion 30a of the fan casing 25.

The top wall 53 connects upper ends of the guide walls 52a, 52b. The top wall 53 is opposed to the bottom wall 5 of the first housing 4. Thus, the adapter receptacle 51 is surrounded by the bottom wall 5 of the first housing 4, the guide walls 52a, 52b, the top wall 53, and the one linear portion 30a of the fan casing 25.

In other words, the adapter receptacle 51 is partitioned so as to be an independent closed space inside the first housing 4 and also has an opening 54 at a termination positioned on the opposite side of the sidewall 7a. The opening 54 is blocked by the one linear portion 30a of the fan casing 25.

Further, the first housing 4 has an insertion opening 55 to insert the AC adapter 18 into the adapter receptacle 51 or remove the AC adapter 18 therefrom. The insertion opening 55 is formed in the left sidewall 7a of the first housing 4. The insertion opening 55 has a horizontal opening shape matching the case 40 of the AC adapter 18 and also is opposed to the one linear portion 30a of the fan casing 25.

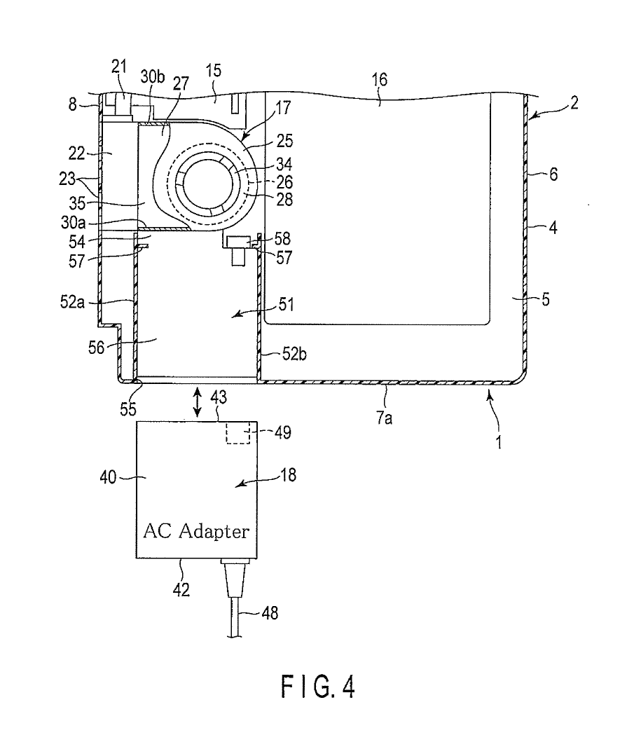

As shown in FIGS. 4 and 5, the fan casing 25 has a heat receiving unit 56 extended toward the adapter receptacle 51. The heat receiving unit 56 is an element integrally formed in the first end plate 27 made of metal and constitutes a portion of the fan casing 25. The heat receiving unit 56 is formed in a flat plate shape and stacked on the bottom wall 5 of the first housing 4 to be the bottom of the adapter receptacle 51.

As shown in FIG. 4, the AC adapter 18 is removably inserted into the adapter receptacle 51 from the insertion opening 55 in a posture in which the output plug 49 is leading. More specifically, when the AC adapter 18 is inserted through the insertion opening 55, the case 40 of the AC adapter 18 is slidably sandwiched between the guide walls 52a, 52b of the adapter receptacle 51 and also slidably sandwiched between the top wall 53 of the adapter receptacle 51 and the heat receiving unit 56 of the fan casing 25.

Thus, the AC adapter 18 is inserted into the adapter receptacle 51 while the insertion direction thereof is guided by the guide walls 52a, 52b, the top wall 53, and the heat receiving unit 56. At this point, the undersurface 44 as a portion of the surface of the case 40 is totally in contact with the heat receiving unit 56 extended from the fan casing 25.

When the AC adapter 18 is inserted into the adapter receptacle 51 up to a position where the front face 42 of the case 40 of the AC adapter 18 blocks the insertion opening 55, the rear face 43 of the case 40 hits stoppers 57 projecting into the adapter receptacle 51 from the guide walls 52a, 52b. Accordingly, the insertion position of the AC adapter 18 is determined and also the output plug 49 of the AC adapter 18 is connected to a connector 58 arranged at the termination of the adapter receptacle 51. As a result, a transition to a state in which the AC adapter 18 and the portable computer 1 are electrically connected occurs.

When the AC adapter 18 is removably inserted into the adapter receptacle 51, it is desirable to install a lock mechanism that locks the AC adapter 18 in a fixed position for the adapter receptacle 51. When the AC adapter 18 is inserted into the fixed position of the adapter receptacle 51, the lock mechanism is caught by the case 40 of the AC adapter 18 so that the AC adapter 18 is held in the adapter receptacle 51 in a way that prevents the AC adapter 18 from dropping off.

According to the first embodiment, when the AC adapter 18 is accommodated in the adapter receptacle 51 of the first housing 4, the undersurface 44 of the case 40 of the AC adapter 18 is totally in contact with the heat receiving unit 56 extended from the fan casing 25. Through this contact, the AC adapter 18 is thermally connected to the heat receiving unit 56 to be a portion of the fan casing 25.

Therefore, heat generated when the AC adapter 18 converts AC into DC is conducted to the heat receiving unit 56 from the case 40 of the AC adapter 18 and also diffused to the fan casing 25 via the heat receiving unit 56. The heat of the AC adapter 18 diffused to the fan casing 25 is released out of the first housing 4 by heat exchange with a cooling air flowing inside the fan casing 25.

Therefore, heat dissipation properties of the AC adapter 18 accommodated in the adapter receptacle 51 of the first housing 4 can be enhanced so that a temperature rise inside the first housing 4 can be prevented.

Further, the centrifugal fan 17 is an existing element that forcibly cools the CPU 20 and thus, a dedicated cooling element that promotes heat dissipation properties of the AC adapter 18 is not needed. Therefore, increasing complexity of the configuration of the portable computer 1 can be avoided and also the configuration is advantageous to maintain compactness of the portable computer 1.

In addition, the adapter receptacle 51 into which the AC adapter 18 is inserted is an independent closed space inside the first housing 4. Thus, heat of the AC adapter 18 is not released directly into the first housing 4 and also in this respect, the configuration is advantageous to prevent a rise of the internal temperature of the first housing 4.

Furthermore, even if a conductive component, for example, a metal clip slips into the adapter receptacle 51 from the insertion opening 55 while the AC adapter 18 is removed from the adapter receptacle 51, the conductive component remains in the adapter receptacle 51. Thus, the conductive component can be prevented from entering the inside of the first housing 4 where circuit elements like the motherboard 15 are contained.

Further, the heat receiving unit 56 of the fan casing 25 is in contact with the undersurface 44 of the case 40 of the AC adapter 18 and receives heat of the AC adapter 18 in a position that is different from the location where the output plug 49 of the AC adapter 18 is connected to the connector 58. Therefore, the heat receiving unit 56 made of metal does not interfere with the output plug 49.

In the first embodiment, all of the first end plate 27, the second end plate 28, and the side plate 29 constituting the fan casing 25 are made of metal. However, for example, only the first end plate 27 where the heat receiving unit 56 is provided may be made of metal and the second end plate 28 and the side plate 29 may be made of synthetic resin.

Further, the insertion opening 55 through which the AC adapter 18 is inserted or removed may be covered with a cover that can be removed or opened/closed.

In addition, the heating module is not limited to the AC adapter. For example, an additional memory having a plurality of semiconductor packages that generate heat is also included in the heating module.

### Second Embodiment

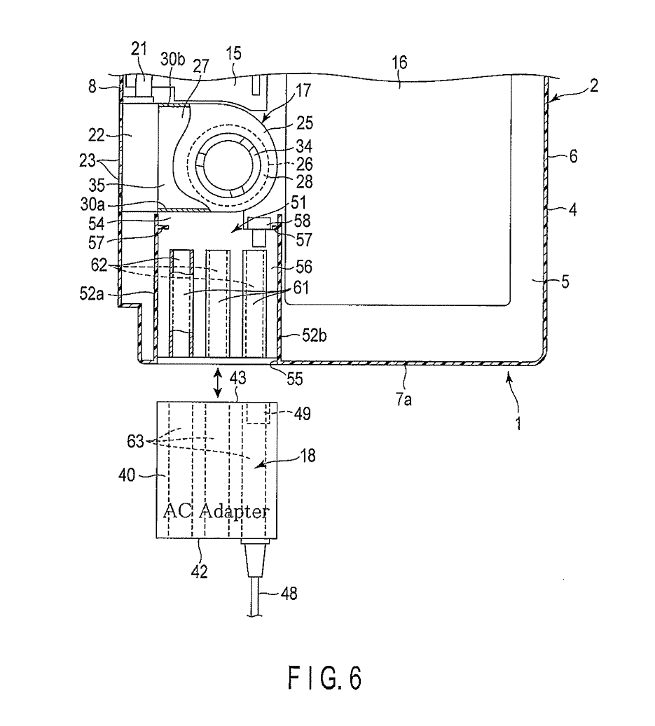

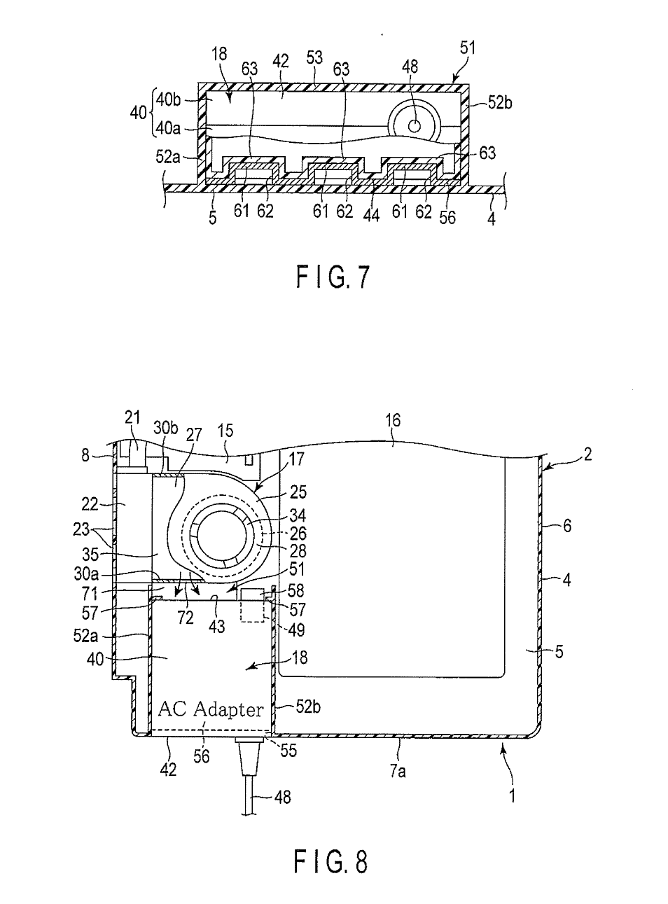

FIGS. 6 and 7 disclose the second embodiment.

The second embodiment is different from the first embodiment in a configuration of a case 40 of an AC adapter 18 and a heat receiving unit 56 of a fan casing 25. The other configuration of a portable computer 1 is the same as in the first embodiment. Thus, in the second embodiment, the same reference numerals are attached to the same structural elements as those in the first embodiment and the description thereof is thereby omitted.

As shown in FIGS. 6 and 7, a plurality of heights 61 is provided in the heat receiving unit 56 of the fan casing 25. The heights 61 extend straight along the insertion direction of the AC adapter 18 and are arranged in parallel with a space therebetween in the depth direction of a first housing 4.

According to the present embodiment, the height 61 has an angular shape projecting from the heat receiving unit 56 toward an adapter receptacle 51 while having substantially the same thickness as the heat receiving unit 56. Thus, when the heat receiving unit 56 is viewed from the direction of a bottom wall 5 of the first housing 4, a plurality of groove portions 62 is formed in positions corresponding to the heights 61 of the heating portion. One end of the groove portion 62 is open toward the termination of the adapter receptacle 51. The other end of the groove portion 62 is open toward an insertion opening 55 of the first housing 4.

A plurality of recesses 63 corresponding to the heights 61 is formed in a lower case 40b of the AC adapter 18. The recesses 63 extend straight along the insertion direction of the AC adapter 18 and are arranged in parallel with a space therebetween in a direction perpendicular to the insertion direction of the AC adapter 18.

When the AC adapter 18 is inserted into the adapter receptacle 51 through the insertion opening 55 of the first housing 4, an undersurface 44 of the case 40 of the AC adapter 18 is slidably comes into contact with the heat receiving unit 56 of the fan casing 25. In addition, the heights 61 of the heat receiving unit 56 are slidably engaged with the recesses 63 of the case 40 and so the surface of the height 61 is totally in contact with the inner surface of the recesses 63.

According to the second embodiment, the heights 61 of the heat receiving unit 56 and the recesses 63 of the case 40 are in contact like being engaged with each other while the AC adapter 18 is accommodated in the adapter receptacle 51. Thus, the contact area between the AC adapter 18 and the heat receiving unit 56 increases when compared with the first embodiment so that heat of the AC adapter 18 can efficiently be conducted to the heating receiving unit 56.

Therefore, heat dissipation properties of the AC adapter 18 accommodated in the adapter receptacle 51 can adequately be secured so that a temperature rise inside the first housing 4 can be prevented.

In the second embodiment, the heights 61 are provided in the heat receiving unit 56 and also the recesses 63 are provided in the case 40 of the AC adapter 18. However, the relationship between the heights 61 and the recesses 63 are not limited the above relationship and, for example, the recesses 63 may be provided in the heat receiving unit 56 and the heights 61 may be provided in the case 40 of the AC adapter 18.

Further, the shapes of the heights 61 and the recesses 63 are not limited to those in the second embodiment. For example, many waveform irregularities may be provided in each of the heat receiving unit 56 and the case 40 of the AC adapter 18 to cause irregularities of the heat receiving unit 56 and irregularities of the case 40 to engage with each other.

### Third Embodiment

FIGS. 8 to 10 disclose the third embodiment.

The third embodiment is different from the second embodiment in that a portion of a cooling air discharged from a centrifugal fan 17 is guided to an adapter receptacle 51. The other configuration of a portable computer 1 is the same as in the second embodiment. Thus, in the third embodiment, the same reference numerals are attached to the same structural elements as those in the second embodiment and the description thereof is thereby omitted.

As shown in FIG. 8, a space 71 is formed between a rear face 43 of a case 40 of an AC adapter 18 and one linear portion 30a of a fan casing 25. An air outlet 72 is formed in the one linear portion 30a of the fan casing 25 facing the space 71. The air outlet 72 is positioned between an outer circumferential portion of an impeller 26 and an exhaust port 35. Further, the air outlet 72 is open to the space 71 and also opposed to the rear face 43 of the case 40.

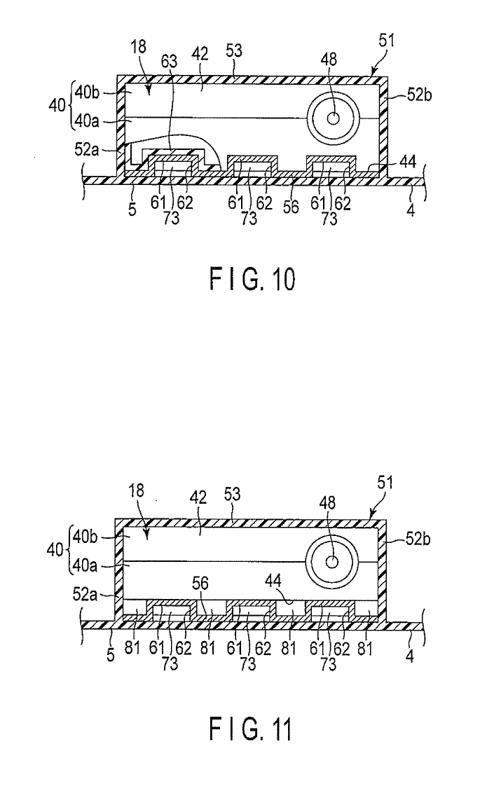

Further, as shown in FIG. 10, groove portions 62 of a heat receiving unit 56 constitute a plurality of first air courses 73 in cooperation with a bottom wall 5 of a first housing 4. The first air courses 73 extend straight along the insertion direction of the AC adapter 18. An upstream end of the first air course 73 is open to the space 71 via one end of the groove portion 62. A downstream end of the first air course 73 is open to an insertion opening 55 of the first housing 4 via the other end of the groove portion 62.

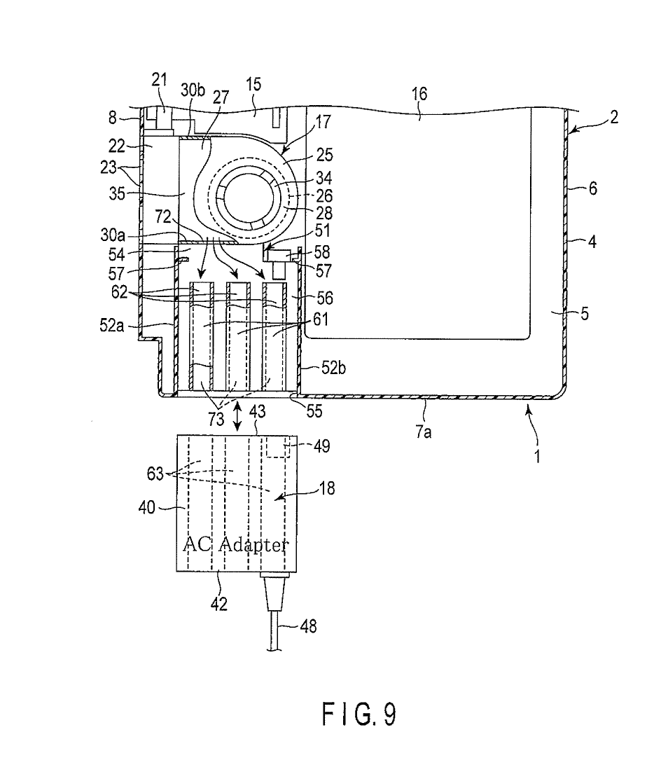

According to the third embodiment, a portion of the cooling air discharged from an outer circumferential portion of an impeller 26 into the fan casing 25 is discharged, as indicated by arrows in FIGS. 8 and 9, into the space 71 from the air outlet 72. The cooling air discharged into the space 71 is directly blown against the rear face 43 of the case 40 of the AC adapter 18 to forcibly cool the AC adapter 18.

Further, the cooling air discharged into the space 71 flows into the first air courses 73 from one end of the groove portions 62 of the heat receiving unit 56. The air having flown into the first air courses 73 flows along the first air courses 73 and also cools the heat receiving unit 56 forcibly in the course of the flow. The cooling air having cooled the heat receiving unit 56 is discharged out of the first housing 4 after passing through the insertion opening 55 from the other end of the groove portion 62.

According to the third embodiment, the AC adapter 18 in the adapter receptacle 51 can forcibly be cooled by using the cooling air discharged into the space 71 from the air outlet 72 of the fan casing 25. In addition, the cooling air flows along the first air courses 73 formed between the heat receiving unit 56 of the fan casing 25 and the bottom wall 5 of the first housing 4 and so the heat receiving unit 56 receiving heat from the AC adapter 18 can forcibly be cooled.

As a result, heat dissipation properties of the AC adapter 18 accommodated in the adapter receptacle 51 can be enhanced still further.

In addition, the cooling air having cooled the AC adapter 18 and the heat receiving unit 56 is discharged out of the first housing 4 from the insertion opening 55. The flow of the cooling air in the adapter receptacle 51 is thereby made smooth, preventing a local build-up of heat inside the first housing 4.

### Fourth Embodiment

FIG. 11 discloses the fourth embodiment.

The fourth embodiment is different from the third embodiment in that an undersurface 44 of a case 40 of an AC adapter 18 is flat. The other configuration is the same as in the third embodiment.

As shown in FIG. 11, the flat undersurface 44 of the case 40 is in surface contact with tip surfaces of heights 61 of a heat receiving unit 56 while the AC adapter 18 is accommodated in the adapter receptacle 51. Thus, the undersurface 44 of the case 40 is a distance corresponding to the height of the height 61 away from the surface of the heat receiving unit 56. Thus, a plurality of second air courses 81 partitioned by the heights 61 is formed between the undersurface 44 of the case 40 and the surface of the heat receiving unit 56.

The second air courses 81 extend straight along the heights 61. The upstream end of the second air course 81 is open to a space 71. Further, the downstream end of the second air course 81 is open to an insertion opening 55.

According to the fourth embodiment, a cooling air discharged into the space 71 from an the air outlet 72 of a fan casing 25 flows into both of first air courses 73 and the second air course 81. The cooling air flowing into the first air courses 73 cools, like in the third embodiment, the heat receiving unit 56 forcibly.

The cooling air flowing into the second air courses 81 flows along the heat receiving unit 56 and the undersurface 44 of the case 40. The cooling air having cooled the heat receiving unit 56 and the case 40 is discharged out of a first housing 4 from the insertion opening 55.

According to the fourth embodiment, the AC adapter 18 inside the adapter receptacle 51 can directly be cooled by the cooling air flowing through the second air courses 81. In addition, the heat receiving unit 56 is in contact with the cooling air flowing through both of the first air courses 73 and the second air course 81 and thus, the heat receiving unit 56 can efficiently be cooled.

Therefore, heat dissipation properties of the AC adapter 18 accommodated in the adapter receptacle 51 are enhanced still further.

### Fifth Embodiment

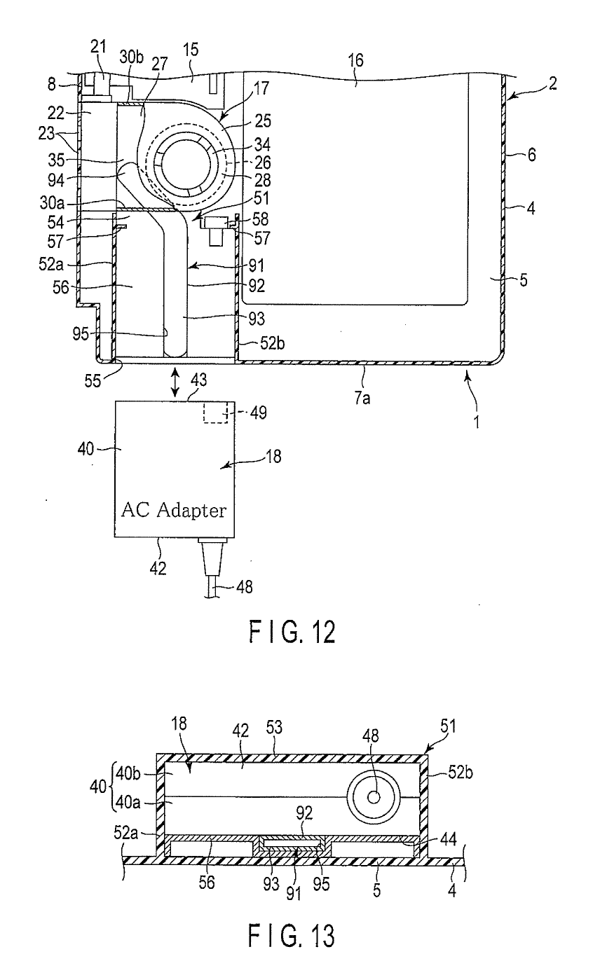

FIGS. 12 and 13 disclose the fifth embodiment.

The fifth embodiment is different from the first embodiment in that heat of an AC adapter 18 is actively transferred to a fan casing 25. The other configuration of a portable computer 1 is the same as in the first embodiment. Thus, in the fifth embodiment, the same reference numerals are attached to the same structural elements as those in the first embodiment and the description thereof is thereby omitted.

As shown in FIGS. 12 and 13, a heat pipe 91 is integrally incorporated in an area from a heat receiving unit 56 up to a first end plate 27 of the fan casing 25. The heat pipe 91 includes a flat container 92 filled with a working fluid. The container 92 has a heat receiving edge 93 and a heat radiating edge 94.

The heat receiving edge 93 of the container 92 extends straight along the insertion direction of the AC adapter 18. The heat receiving edge 93 is thermally connected to the heat receiving unit 56 by being embedded in a groove 95 provided in the heat receiving unit 56. Thus, the heat receiving edge 93 of the container 92 is positioned in the same plane as the heat receiving unit 56 without projecting from the heat receiving unit 56 of the fan casing 25.

The heat radiating edge 94 of the container 92 is thermally connected to the first end plate 27 of the fan casing 25. The heat radiating edge 94 is exposed to a flowing course of a cooling air from an impeller 26 toward an exhaust port 35.

According to the fifth embodiment, as shown in FIG. 13, an undersurface 44 of a case 40 of the AC adapter 18 is in contact with both of the heat receiving unit 56 and the heat receiving edge 93 of the heat pipe 91 while the AC adapter 18 is accommodated in an adapter receptacle 51.

Thus, heat of the AC adapter 18 is directly conducted to the heat receiving edge 93 of the heat pipe 91 from the AC adapter 18 and also conducted to the heat receiving edge 93 of the heat pipe 91 indirectly from the heat receiving unit 56 of the fan casing 25.

The working fluid returned to the heat receiving edge 93 is heated by the heat conduction to become a vapor. The vapor flows from the heat receiving edge 93 toward the heat radiating edge 94 and also condenses at the heat radiating edge 94. Heat released by the condensation is diffused to the fan casing 25 by heat conduction to the first end plate 27. The heat of the AC adapter 18 diffused to the fan casing 25 is released out of a first housing 4 by heat exchange with a cooling air flowing inside the fan casing 25.

The working fluid liquefied at the heat radiating edge 94 is returned to the heat receiving edge 93 by a capillary force to receive heat of the AC adapter 18 again. By repeated evaporation and condensation of the working fluid described above, heat of the AC adapter 18 is transferred to the fan casing 25.

According to the fifth embodiment, by using the heat pipe 91 at the same time, heat of the AC adapter 18 can efficiently be released out of the first housing 4, enhancing heat dissipation properties of the AC adapter 18.

### Sixth Embodiment

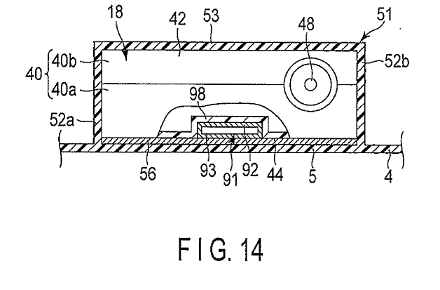

FIG. 14 discloses the sixth embodiment related to the fifth embodiment.

In the sixth embodiment, a heat receiving edge 93 of a heat pipe 91 is fixed onto a heat receiving unit 56 without being embedded in the heat receiving unit 56 of a fan casing 25. The heat receiving edge 93 extends straight along the insertion direction of an AC adapter 18.

On the other hand, a recess 98 is formed in an undersurface 44 of a case 40 of the AC adapter 18. The recess 98 is an element into which the heat receiving edge 93 of the heat pipe 91 is slidably inserted and extends straight along the insertion direction of the AC adapter 18. Further, the recess 98 extends along the entire length of the undersurface 44 of the case 40 and is open to each of a corner defined by the undersurface 44 of the case 40 and a front face 42 and a corner defined by the undersurface 44 of the case 40 and a rear face 43.

According to the sixth embodiment, when the AC adapter 18 is inserted into an adapter receptacle 51 through an insertion opening 55, the heat receiving edge 93 of the heat pipe 91 enters the recess 98 of the case 40 to thermally connect to the AC adapter 18.

Thus, like in the fifth embodiment, heat of the AC adapter 18 can actively be transferred to the fan casing 25 by using the heat pipe 91 so that heat dissipation properties of the AC adapter 18 can be enhanced.

In addition, in the sixth embodiment, the heat receiving edge 93 of the heat pipe 91 projecting above the heat receiving unit 56 extends straight in the insertion direction of the AC adapter 18. Therefore, when the AC adapter 18 is inserted into for removed from the adapter receptacle 51, the heat receiving edge 93 of the heat pipe 91 can be used as a guide rail.

### Seventh Embodiment

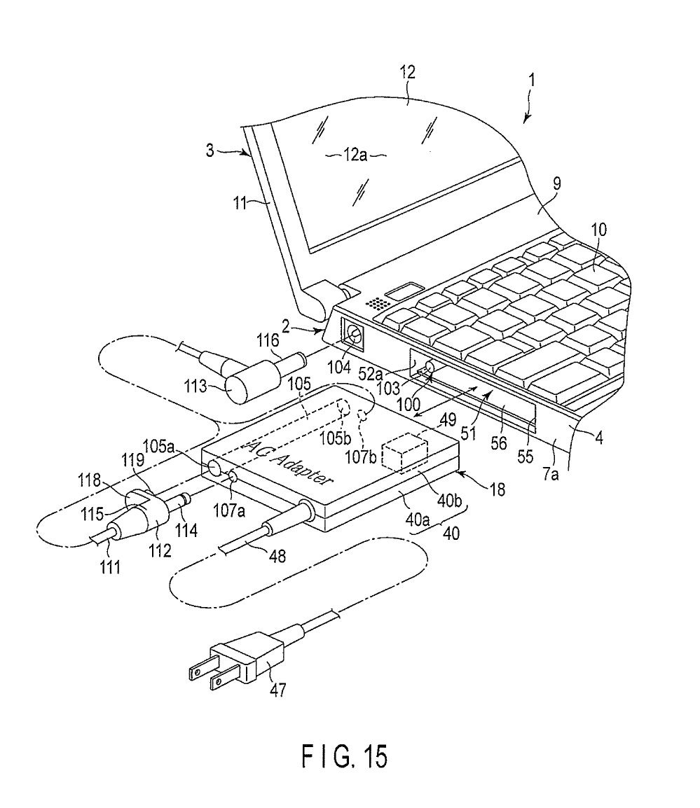

FIGS. 15 to 18 disclose the seventh embodiment.

The seventh embodiment is different from the first embodiment in a configuration in which an AC adapter 18 and a portable computer 1 are electrically connected and a configuration that enhances heat dissipation properties of the AC adapter 18. The other configuration of the portable computer 1 is the same as in the first embodiment. Thus, in the seventh embodiment, the same reference numerals are attached to the same structural elements as those in the first embodiment and the description thereof is thereby omitted.

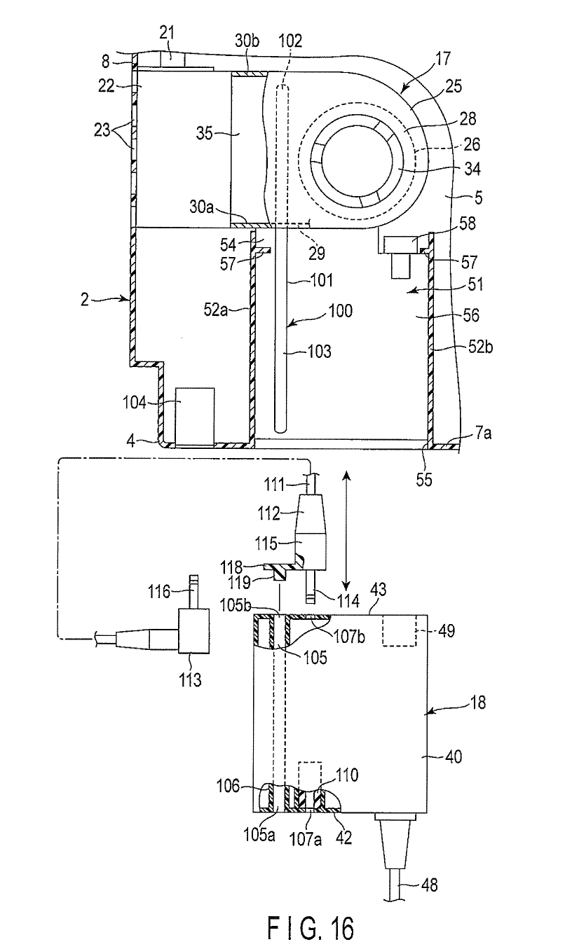

As shown in FIG. 16, a heat pipe 100 is arranged extending between a centrifugal fan 17 and an adapter receptacle 51. The heat pipe 100 includes a container 101 filled with a working fluid. The container 101 is formed from a straight round pipe. The container 101 includes a heat radiating edge 102 and a heat receiving edge 103.

The heat radiating edge 102 is introduced into a fan casing 25 by passing through a linear portion 30a of the fan casing 25. The heat radiating edge 102 is thermally connected onto a first end plate 27 of the fan casing 25 between an impeller 26 and an exhaust port 35.

The heat receiving edge 103 is projected from the fan casing 25 toward the adapter receptacle 51. The heat receiving edge 103 extends along the insertion direction of the AC adapter 18 inside the adapter receptacle 51 and the tip thereof reaches the vicinity of an insertion opening 55.

In addition, the heat receiving edge 103 is away from an inner surface of the adapter receptacle 51 and a heat receiving unit 56 of the fan casing 25. Thus, the heat receiving edge 103 is maintained in a floating state inside the adapter receptacle 51.

Further, a power supply connector 104 is arranged inside a first housing 4. The power supply connector 104 is exposed to the outside of the first housing 4 in a position adjacent to the insertion opening 55 of the adapter receptacle 51.

On the other hand, a case 40 of the AC adapter 18 has an insertion path 105. The insertion path 105 is an element into which the heat receiving edge 103 of the heat pipe 100 is removably inserted when the AC adapter 18 is inserted into the adapter receptacle 51 through the insertion opening 55.

The insertion path 105 passes through the case 40 in a straight line along the insertion direction of the AC adapter 18 and also is isolated from the inside of the case 40 via a cylindrical partition wall 106 integrated with the case 40. The insertion path 105 has a first opening 105a open to the front face 42 of the case 40 and a second opening 105b open to the rear face 43 of the case 40.

Further, a first insertion hole 107a adjacent to the first opening 105a is provided in the front face 42 of the case 40. Similarly, a second insertion hole 107b adjacent to the second opening 105b is provided in the rear face 43 of the case 40.

When the AC adapter 18 is inserted into the adapter receptacle 51 through the insertion opening 55 of the first housing 4, the heat receiving edge 103 of the heat pipe 100 enters the insertion path 105 through the second opening 105b. While the AC adapter 18 is accommodated in a fixed position of the adapter receptacle 51, the heat receiving edge 103 of the heat pipe 100 is in contact with the inner surface of the partition wall 106 defining the insertion path 105 along the entire length thereof. Through this contact, the AC adapter 18 is thermally connected to the heat receiving edge 103 of the heat pipe 100.

The AC adapter 18 in the present embodiment includes an output connector 110 so as to be usable even when removed from the adapter receptacle 51. The output connector 110 is connected to the output terminal of a circuit module 41 and is exposed to the outside of the AC adapter 18 through the first insertion hole 107a formed in the front face 42 of the case 40.

The output connector 110 can be connected to the portable computer 1 via a removable output cable 111. The output cable 111 has a first output plug 112 and a second output plug 113.

The first output plug 112 is provided at one end of the output cable 111. The first output plug 112 has a plug body 115 made of synthetic resin from which a pin terminal 114 projects. The pin terminal 114 can selectively be inserted into the first insertion hole 107a or the second insertion hole 107b of the AC adapter 18 and can also be connected to the output connector 110 via the first insertion hole 107a.

The second output plug 113 is provided at the other end of the output cable 111. A pin terminal 116 held by the second output plug 113 can be connected to the power supply connector 104 of the first housing 4.

A cover portion 118 is integrally formed in the plug body 115 of the first output plug 112. The cover portion 118 is projected from the plug body 115 along the front face 42 or the rear face 43 of the case 40 and has a projection 119 fitted into the first opening 105a or the second opening 105b of the insertion path 105.

The projection 119 blocks the first opening 105a by being fitted into the first opening 105a of the insertion path 105 when the pin terminal 114 of the first output plug 112 is connected to the output connector 110 via the first insertion hole 107a. Further, the projection 119 blocks the second opening 105b by being fitted into the second opening 105b of the insertion path 105 when the pin terminal 114 of the first output plug 112 is inserted into the second insertion hole 107b.

In the present embodiment, the first output plug 112 is inserted into the second insertion hole 107b when the AC adapter 18 is removed from the adapter receptacle 51. Accordingly, the output cable 111 is held by the AC adapter 18 and also the second opening 105b of the insertion path 105 is closed by the projection 119 of the plug body 115.

When the AC adapter 18 is accommodated in the adapter receptacle 51 and used, as shown in FIG. 16, the pin terminal 114 of the first output plug 112 is pulled out of the second insertion hole 107b of the case 40. Accordingly, the projection 119 of the plug body 115 is removed from the second opening 105b of the insertion path 105 to unblock the second opening 105b.

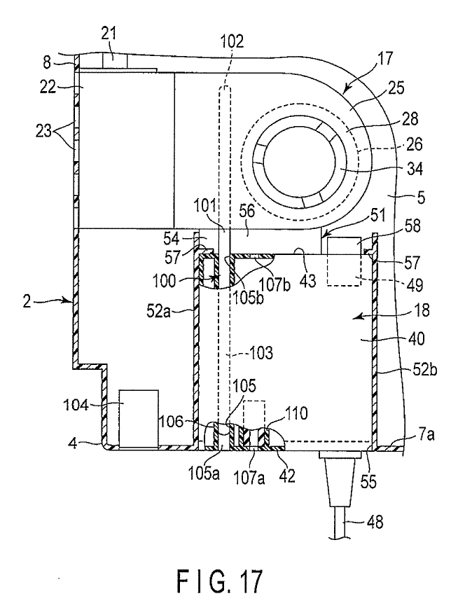

Thereafter, like in the first embodiment, the AC adapter 18 is inserted into the adapter receptacle 51 through the insertion opening 55. The AC adapter 18 is inserted into the adapter receptacle 51 while the insertion direction thereof is guided by guide walls 52a, 52b, a top wall 53, and the heat receiving unit 56. At this point, an undersurface 44 of the case 40 is totally in contact with the heat receiving unit 56 of the fan casing 25. Further, as shown in FIG. 17, the heat receiving edge 103 of the heat pipe 100 is inserted into the insertion path 105 from the second opening 105b.

When the rear face 43 of the case 40 hits stoppers 57 of the guide walls 52a, 52b, the output plug 49 of the AC adapter 18 is connected to a connector 58 of the adapter receptacle 51. In addition, the heat receiving edge 103 of the heat pipe 100 is in contact with the inner surface of the partition wall 106 of the insertion path 105 along the entire length thereof. Accordingly, the AC adapter 18 is thermally connected to the fan casing 25 via the heat pipe 100.

According to the seventh embodiment, while the AC adapter 18 is accommodated in the adapter receptacle 51, heat emitted from the AC adapter 18 is conducted from the AC adapter 18 to the heat receiving unit 56 and also diffused by heat conduction from the heat receiving unit 56 to the fan casing 25. The heat of the AC adapter 18 diffused to the fan casing 25 is released out of the first housing 4 by heat exchange with a cooling air flowing inside the fan casing 25.

In addition, the heat receiving edge 103 of the heat pipe 100 is plugged in the insertion path 105 of the AC adapter 18 and thus, heat of the AC adapter 18 is directly conducted to the heat receiving edge 103 of the heat pipe 100. As a result, heat of the AC adapter 18 is actively transferred to the fan casing 25 by the operation of a working fluid with which the heat pipe 100 is filled. The heat of the AC adapter 18 diffused to the fan casing 25 is released out of the first housing 4 by heat exchange with a cooling air flowing inside the fan casing 25.

Therefore, heat dissipation properties of the AC adapter 18 accommodated in the adapter receptacle 51 of the first housing 4 can be enhanced so that a temperature rise inside the first housing 4 can be prevented.

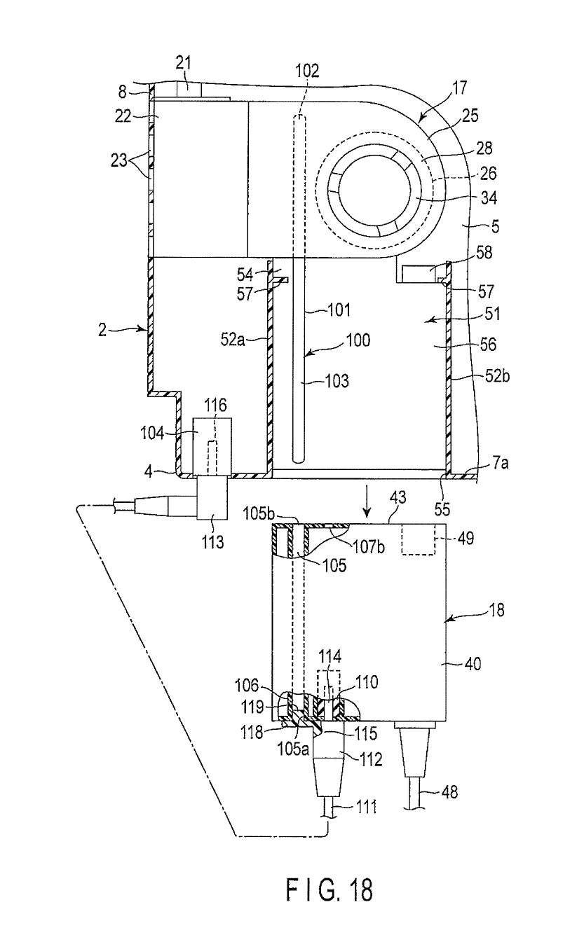

In the seventh embodiment, the portable computer can be used even when the AC adapter 18 is removed from the adapter receptacle 51 by using the output cable 111. FIG. 18 shows a state in which the AC adapter 18 removed out of the adapter receptacle 51 and the portable computer 1 are connected by the output cable 111.

As shown in FIG. 18, the first output plug 112 of the output cable 111 is connected to the output connector 110 of the AC adapter 18 by inserting the pin terminal 114 into the first insertion hole 107a of the case 40.

At this point, the first opening 105a is closed by the cover portion 118 of the plug body 115 being overlaid with the front face 42 of the case 40 and the projection 119 projected from the cover portion 118 being fitted into the first opening 105a of the insertion path 105.

The second output plug 113 of the output cable 111 is connected to the power supply connector 104 of the first housing 4.

While the AC adapter 18 is removed out of the adapter receptacle 51, it is desirable to cover the insertion opening 55 with a cover to prevent dust or foreign matter from entering the adapter receptacle 51 through the insertion opening 55.

In the seventh embodiment, the heat receiving edge 103 of the heat pipe 100 passes through the case 40 of the AC adapter 18, but the embodiment is not limited to the above example. For example, a groove along the insertion direction of the AC adapter 18 may be formed in the side face of the case 40 so that the heat receiving edge 103 of the heat pipe 100 is plugged in.

Further, the heat pipe may be omitted so that heat of the AC adapter 18 is dissipated to the fan casing 25 only by heat conduction from the AC adapter 18 to the fan casing 25.

### Eighth Embodiment

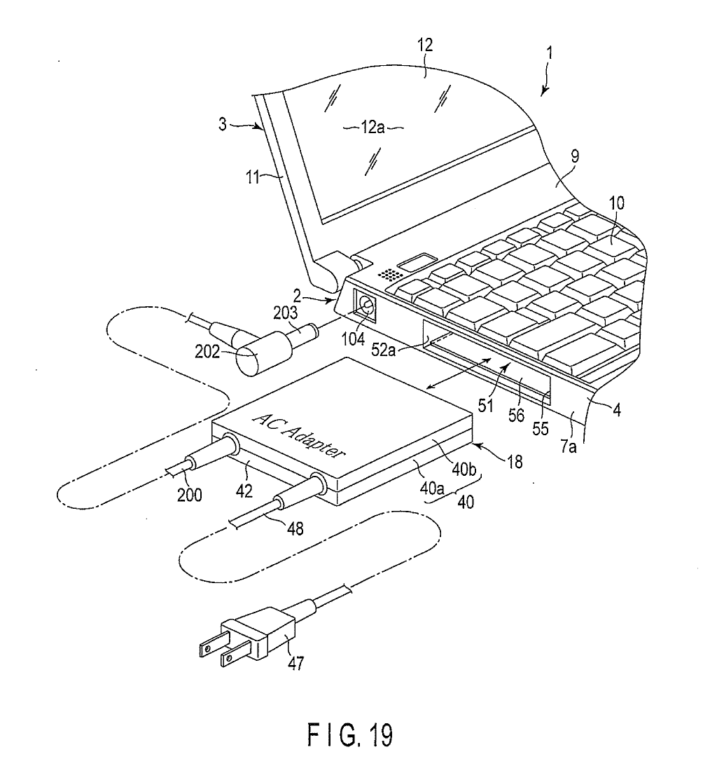

FIG. 19 discloses the eighth embodiment.

The eighth embodiment is different from the first embodiment in that an AC adapter 18 accommodated in an adapter receptacle 51 has an output cable 200.

As shown in FIG. 19, a power supply connector 104 is arranged inside a first housing 4. The power supply connector 104 is exposed to the outside of the first housing 4 in a position adjacent to an insertion opening 55 of the adapter receptacle 51.

The output cable 200 of the AC adapter 18 is an element that transmits power transformed from AC to DC by the AC adapter 18 and is led to the outside of the AC adapter 18 from the front face 42 of the case 40. An output plug 202 is provided at the tip of the output cable 200. The output plug 202 has a pin terminal 203. The pin terminal 203 can be connected to the power supply connector 104 from outside the first housing 4.

According to the eighth embodiment, the AC adapter 18 has a power cord 48 for input and the output cable 200 for output. Thus, by connecting the output plug 202 of the output cable 200 to the power supply connector 104 of a portable computer 1, the AC adapter 18 can be used even while the AC adapter 18 is removed out of the first housing 4 from the adapter receptacle 51.

### Ninth Embodiment

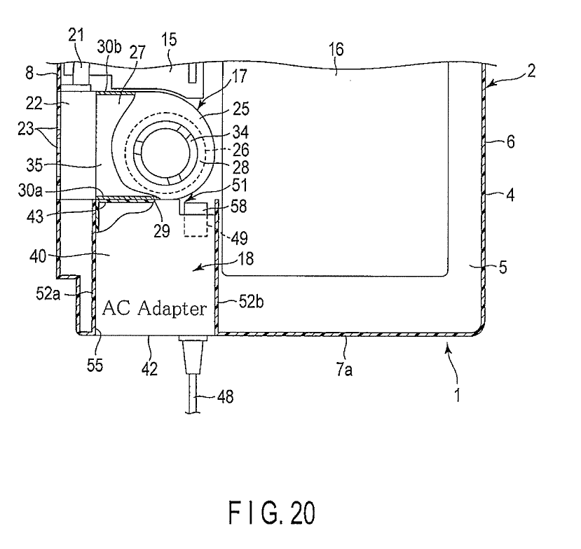

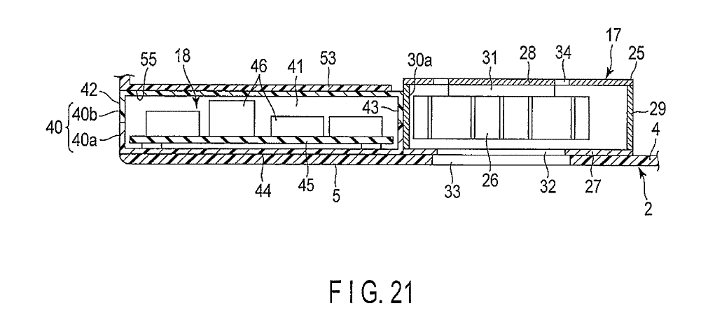

FIGS. 20 and 21 disclose the ninth embodiment.

The ninth embodiment is different from the first embodiment in a configuration to conduct heat of an AC adapter 18 to a fan casing 25. The other configuration of a portable computer 1 is the same as in the first embodiment. Thus, in the ninth embodiment, the same reference numerals are attached to the same structural elements as those in the first embodiment and the description thereof is thereby omitted.

As shown in FIGS. 20 and 21, one linear portion 30a of a side plate 29 of the fan casing 25 closes the termination of an adapter receptacle 51 so as to be opposed to an insertion opening 55. Further, the one linear portion 30a extends in a direction perpendicular to the insertion direction of the AC adapter 18 inside a first housing 4.

When the AC adapter 18 is inserted into the adapter receptacle 51 up to a position where a front face 42 of a case 40 of the AC adapter 18 blocks the insertion opening 55, an output plug 49 of the AC adapter 18 is connected to a connector 58 arranged at the termination of the adapter receptacle 51.

Further, a rear face 43 of the case 40 hits the one linear portion 30a of the fan casing 25. Accordingly, the insertion position of the AC adapter 18 is determined and also the rear face 43 of the case 40 is totally in contact with the one linear portion 30a. Therefore, the AC adapter 18 is thermally connected to the one linear portion 30a as a portion of the fan casing 25.

According to the ninth embodiment, heat emitted from the AC adapter 18 is directly conducted from the AC adapter 18 to the side plate 29 of the fan casing 25 and also diffused to the fan casing 25. The heat of the AC adapter 18 diffused to the fan casing 25 is released out of the first housing 4 by heat exchange with a cooling air flowing inside the fan casing 25.

Therefore, heat dissipation properties of the AC adapter 18 accommodated in the adapter receptacle 51 of the first housing 4 can be secured so that a temperature rise inside the first housing 4 can be prevented.

In the ninth embodiment, irregularities may be formed in each of the rear face 43 of the case 40 and the one linear portion 30a of the fan casing 25 to cause irregularities of the rear face 43 and irregularities of the linear portion 30a to engage with each other.

According to the above configuration, a contact area of the AC adapter 18 and the fan casing 25 can be increased so that heat of the AC adapter 18 can efficiently be conducted to the fan casing 25.

Further, a heat pipe may be arranged extending between the adapter receptacle 51 and the fan casing 25 to actively transfer heat of the AC adapter 18 accommodated in the adapter receptacle 51 to the fan casing 25 via the heat pipe.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a fan including a fan casing at least a portion of which is made of metal and accommodated in the housing; and
a heating module removably accommodated in the housing and thermally connected to the fan casing by being brought in contact with the portion of the fan casing inside the housing.

2. The electronic apparatus of claim 1, wherein the heating module is an AC adapter using gallium nitride as a power semiconductor device.

3. An electronic apparatus comprising:
a housing;
a fan including a fan casing at least a portion of which is made of metal and accommodated in the housing; and
an AC adapter removably accommodated in the housing and thermally connected to the fan casing by being brought in contact with the portion of the fan casing inside the housing.

4. The electronic apparatus of claim 3, wherein the AC adapter uses gallium nitride as a power semiconductor device used for power control.

5. The electronic apparatus of claim 2, wherein the housing includes a receptacle in which the AC adapter is removably accommodated and the receptacle is partitioned so as to be a closed space inside the housing.

6. The electronic apparatus of claim 5, wherein the fan casing includes a heat receiving unit extended toward the receptacle and made of the metal and the AC adapter is thermally connected to the heat receiving unit.

7. The electronic apparatus of claim 6, wherein the AC adapter includes a surface for surface contact with the heat receiving unit.

8. The electronic apparatus of claim 7, wherein a plurality of heights is provided on the surface of one of the heat receiving unit and the AC adapter and a plurality of recesses engaged with the heights is provided on the surface of the other.

9. The electronic apparatus of claim 6, wherein the fan casing includes an air outlet through which a portion of a cooling air is blown out toward the AC adapter to form an air course through which the cooling air flows to the heat receiving unit.

10. The electronic apparatus of claim 6, wherein the fan casing includes an air outlet through which a portion of a cooling air is blown out toward the AC adapter to form an air course through which the cooling air flows between the AC adapter and the heat receiving unit.

11. The electronic apparatus of claim 9, wherein the housing includes an insertion opening through which the AC adapter is inserted into or removed from the receptacle and a downstream end of the air course is open to the insertion opening.

12. The electronic apparatus of claim 5, further comprising: a heat pipe includes a heat radiating edge thermally connected to the fan casing and a heat receiving edge projected to the receptacle, wherein the heat receiving edge of the heat pipe is thermally connected to the AC adapter when the AC adapter is accommodated in the receptacle.

13. The electronic apparatus of claim 6, further comprising: a heat pipe extending between the fan casing and the heat receiving unit.

14. The electronic apparatus of claim 2, wherein the housing includes a receptacle in which the AC adapter is removably accommodated in a position adjacent to the fan, the receptacle includes an opening opposed to a portion of the fan casing inside the housing, and the AC adapter contact the portion of the fan casing via the opening.

15. The electronic apparatus of claim 2, further comprising: a heating component accommodated in the housing and a heat sink thermally connected to the heating component, wherein the fan is configured to send the cooling air to the heat sink.

16. An electronic apparatus comprising:
a housing including a receptacle;
a fan including a fan casing at least a portion of which is made of metal and provided inside the housing in a position adjacent to the receptacle to send a cooling air to a heat sink; and
an AC adapter removably inserted into the receptacle, thermally connected to the fan casing by being brought in contact with the portion of the fan casing when the AC adapter is inserted into the receptacle, and using gallium nitride as a power semiconductor device used for power control.

17. The electronic apparatus of claim 16, wherein the fan casing includes a heat receiving unit extended toward the receptacle and made of metal and the AC adapter is overlaid on the heat receiving unit.

18. The electronic apparatus of claim 17, wherein one of the heat receiving unit and the AC adapter is provided with a plurality of heights and the other is provided with a plurality of recesses slidably engaged with the heights and
the heights and the recesses are configured to cooperate to guide an insertion direction of the AC adapter into the receptacle and a removal direction of the AC adapter from the receptacle.

19. The electronic apparatus of claim 16, wherein the receptacle is partitioned so as to be a closed space inside the housing.

20. The electronic apparatus of claim 16, further comprising: a heat pipe includes a heat radiating edge thermally connected to the fan casing and a heat receiving edge projected to the receptacle, wherein the heat receiving edge of the heat pipe is thermally connected to the AC adapter when the AC adapter is inserted into the receptacle.
